(19) United States
(12) Patent Application Publication
(10) Pub. No.: US 2017/0317249 A1
(43) Pub. Date: Nov. 2, 2017

(54) BACKLIGHT UNIT AND SIDE VIEW LIGHT-EMITTING DIODE PACKAGE

(71) Applicant: Seoul Semiconductor Co., Ltd., Ansan-si (KR)

(72) Inventor: Seoung Ho JUNG, Ansan Ho (KR)

(73) Assignee: Seoul Semiconductor Co., Ltd.

(21) Appl. No.: 15/519,762

(22) PCT Filed: Oct. 14, 2015
(86) PCT No.: PCT/KR2015/010845

§ 371 Date: Jul. 20, 2017

(30) Foreign Application Priority Data
Oct. 17, 2014 (KR) 10-2014-0141028

(51) Int. Cl. H01L 33/60; H01L 33/50; H01L 33/48; H01L 33/62; H01L 27/15

(52) U.S. Cl. CPC H01L 33/60; H01L 33/62; H01L 27/153; H01L 33/486; H01L 33/507

(57) ABSTRACT

A backlight unit and a side view light-emitting diode package are disclosed. The backlight unit includes: a light guide plate; and a light-emitting diode package coupled to the side of the light guide plate, and emitting light to the inside of the light guide plate, wherein the light-emitting diode package includes: a substrate; a pair of leads disposed on both ends of the substrate; a light-emitting diode chip mounted on the upper part of the substrate; a reflection unit disposed to surround the sides of the light-emitting diode chip; and a wavelength conversion unit disposed on the upper part of the light-emitting diode chip and the reflection unit. A light-emitting diode chip is directly mounted on a substrate so as to be manufactured such that an ultra-thin or ultra-slim backlight unit and side view light-emitting diode package can be manufactured.

### CROSS-REFERENCE TO RELATED APPLICATIONS

This application is the National Stage Entry of International Application No. PCT/KR2015/010845, filed on Oct. 14, 2015, and claims priority from and the benefit of Korean Patent Application No. 10-2014-0141028, filed on Oct. 17, 2014, each of which is hereby incorporated by reference for all purposes as if fully set forth herein.

### BACKGROUND

### Field

Exemplary embodiments relate to a side-view light-emitting diode package and a backlight unit, and more particularly, to a side-view light-emitting diode package and a backlight unit including the same.

### Discussion Of The Background

Generally, light emitting diode packages are divided into a top-emitting light emitting diode package and a side-view light-emitting diode package. A side-view light-emitting diode package is coupled to a side surface of a light guide plate of a backlight unit and is widely used as a backlight source for a display. Recently, a side-view light-emitting diode package has been used for other various purposes.

Such a side-view light-emitting diode package generally includes a cavity for mounting a light emitting diode on a front surface of a body thereof. In addition, the side-view light-emitting diode package includes lead frames extending outwardly from an inside of the package body through a bottom of the package body and electrically connected to a light emitting diode chip within the cavity. Here, a portion of the lead frame inside the package body is called an internal lead and a portion of the lead frame outside the package body is called an external lead.

Here, the external leads are bent under the bottom of the package body and connected to solder patterns of a substrate through soldering or the like. As a result, the light emitting diode package is mounted on the substrate and electrically connected to the solder patterns on the substrate.

Recently, as the thickness of a display has been reduced, the thickness of a side-view light-emitting diode package has also been reduced. Typical side-view light-emitting diode packages have a thickness of 0.4 T. When the thickness of a side-view light-emitting diode package is further reduced, a space between a light emitting diode chip and a reflector becomes narrower, thereby increasing photo-aging. Thus, such typical side-view light-emitting diode packages have a limit in thickness reduction.

### SUMMARY

Exemplary embodiments of the present inventive concepts provide a side-view light-emitting diode package having a structure which allows further reduction in thickness thereof, and a backlight unit including the same.

In accordance with an exemplary embodiment, a backlight unit includes: a light guide plate; and a light emitting diode package coupled to a side surface of the light guide plate and emitting light into the light guide plate, wherein the light emitting diode package includes: a substrate; a pair of leads formed at opposite ends of the substrate; a light emitting diode chip mounted on the substrate; a reflection portion surrounding a side surface of the light emitting diode chip; and a wavelength conversion portion formed on the light emitting diode chip and the reflection portion.

The reflection portion may cover the substrate having the light emitting diode chip mounted thereon. The reflection portion may be spaced apart from the substrate. The reflection portion may have a width allowing opposite ends thereof to be flush with opposite ends of the pair of leads, respectively, and the wavelength conversion portion may completely cover an upper surface of the reflection portion. Here, the pair of leads may be bent to extend from the opposite ends of the substrate to a lower surface of the substrate.

The pair of leads may extend from an upper surface of the substrate to a lower surface of the substrate to surround the opposite ends of the substrate.

In accordance with another exemplary embodiment, a side-view light-emitting diode package includes: a substrate; a pair of leads formed at opposite ends of the substrate; a light emitting diode chip mounted on the substrate; a reflection portion surrounding a side surface of the light emitting diode chip; and a wavelength conversion portion formed on the light emitting diode chip and the reflection portion.

The reflection portion may cover the substrate having the light emitting diode chip mounted thereon. The reflection portion may be spaced apart from the substrate. The reflection portion may have a width allowing opposite ends thereof to be flush with opposite ends of the pair of leads, respectively, and the wavelength conversion portion may completely cover an upper surface of the reflection portion. Here, the pair of leads may be bent to extend from the opposite ends of the substrate to a lower surface of the substrate.

The pair of leads may extend from an upper surface of the substrate to a lower surface of the substrate to surround the opposite ends of the substrate.

Exemplary embodiments provide a backlight unit and a side-view light-emitting diode package that have an ultra-thin or ultra-slim structure formed by directly mounting a light-emitting diode chip on a substrate.

Exemplary embodiments provides a backlight unit which includes a light guide plate disposed in a direction in which light is emitted from a light emitting diode chip of a side-view light-emitting diode package, thereby maximizing luminous efficacy of the light entering the light guide plate.

### BRIEF DESCRIPTION OF THE DRAWINGS

FIG. 1 is a side view of a backlight unit according to one exemplary embodiment.

FIG. 2 is a cross section view of a side-view light-emitting diode package for a backlight unit according to one exemplary embodiment.

FIG. 3 is a cross section view of a side-view light-emitting diode package for a backlight unit according to another exemplary embodiment.

FIG. 4 is a cross section view of a side-view light-emitting diode package for a backlight unit according to an exemplary embodiment

### DETAILED DESCRIPTION OF THE ILLUSTRATED EMBODIMENTS

Hereinafter, exemplary embodiments of the present inventive concepts will be described with reference to the accompanying drawings.

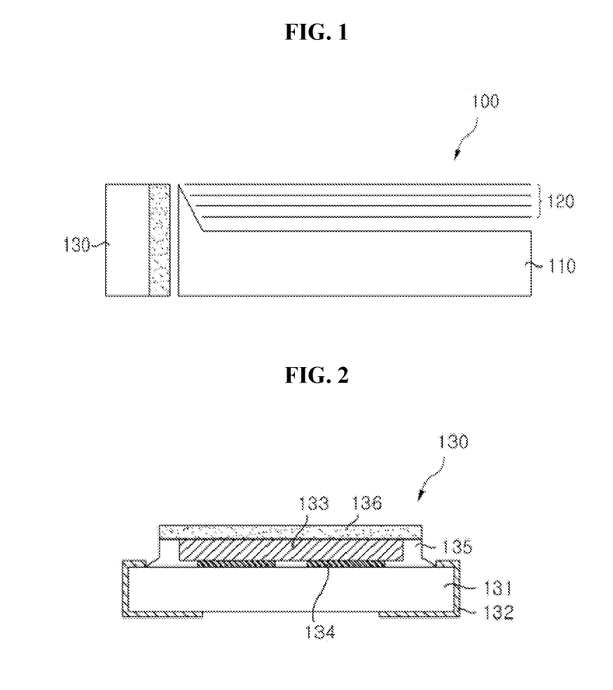

FIG. 1 is a side view of a backlight unit according to one exemplary embodiment and FIG. 2 is a cross section view of a side-view light-emitting diode package for a backlight unit according to one exemplary embodiment.

Referring to FIG. 1, a backlight unit 100 according to one exemplary embodiment includes a light guide plate 110, a plurality of films 120, and a side-view light-emitting diode package 130.

The light guide plate 110 is disposed under a liquid crystal display panel (not shown) and redirects light received from the light emitting diode package to the liquid crystal display panel. Preferably, the light guide plate 110 is formed of a transparent material, for example, transparent poly (methyl methacrylate) (PMMA) or polycarbonate (PC), in order to minimize light loss.

In addition, a predetermined reflective pattern (not shown) for reflecting and scattering light may be formed on a lower surface of the light guide plate 110. For example, the reflective pattern formed on the lower surface of the light guide plate 110 may include a printed pattern or an embossed pattern. Thus, light entering the light guide plate 110 from the side-view light-emitting diode package 130 is reflected and scattered by the reflective pattern, and light incident on an upper surface of the light guide plate 110 at an angle exceeding a certain critical angle exits through the upper surface of the light guide plate 110.

Further, the light guide plate 110 may have a plate shape in which a light entering surface of the light guide plate facing the side-view light-emitting diode package 130 has the same thickness as an opposite surface of the light guide plate, or may have a wedge shape in which the thickness of the light guide plate gradually decreases from the light entering surface toward the opposite surface thereof. Alternatively, a portion of the light guide plate on the light incident surface side may be formed in a wedge shape and a portion of the light guide plate extending from an end of the wedge shape to the opposite surface may have a constant thickness, as shown in FIG. 1.

The films 120 include a diffusion sheet, a prism sheet, an absorbent sheet, and the like. In addition to those shown in FIG. 1, the films 120 may further include a plate-type or sheet-type optical sheet such as a different prism sheet or a protective sheet.

As shown in FIG. 1, the side-view light-emitting diode package 130 is coupled to a side surface of the light guide plate 110 and emits light into the light guide plate 110. Referring to FIG. 2, the side-view light-emitting diode package 130 includes a substrate 131, a pair of leads 132, a light emitting diode chip 133, a reflection portion 135, and a wavelength conversion portion 136.

The light emitting diode chip 133 may be mounted on the substrate 131. The substrate may be formed with a plurality of conductive patterns. The substrate 131 may be, for example, a metal PCB advantageous for heat dissipation, and may be a bar-type substrate having a major axis and a minor axis, without being limited thereto. In one embodiment, the bar-type substrate 131 may have a length of about 1.8T.

The pair of leads 132 is electrically connected to the plurality of conductive patterns of the substrate 131 and is disposed to surround opposite ends of the substrate 131. That is, the pair of leads 132 extends from an upper surface of the substrate 131 to a lower surface of the substrate 131 through a side surface of the substrate. Thus, the pair of leads 132 is formed in a “C” shape, as shown in FIG. 2.

The light emitting diode chip 133 is a semiconductor device that receives electricity from an external power source to emit light at a predetermined wavelength, and a single light emitting diode chip 133 may be provided. In other exemplary embodiments, a plurality of light emitting diode chips 133 may be mounted on the substrate 131. The light emitting diode chip(s) 133 may be directly flip-bonded to the substrate or coupled to the substrate by surface mount technology (SMT) to be electrically connected to the plurality of conductive patterns on the substrate 131.

Since the side-view light-emitting diode package 130 according to the exemplary embodiments does not require a separate wire, a molding portion for protecting the wire is not required and it is not necessary to remove a portion of the wavelength conversion portion 136 to expose an electrode 134.

The reflection portion 135 is formed to surround the light emitting diode chip 133 such that light from the light emitting diode chip 133 can exit only in one direction. In this embodiment, the reflection portion 135 surrounds the light emitting diode chip 133 mounted on the substrate 131, as shown in FIG. 2. In this structure, the reflection portion 135 adjoins both a side surface of the light emitting diode chip 133 and an upper surface of the substrate 131.

In this embodiment, the reflection portion 135 may be formed through a procedure in which, with the light emitting diode chip 133 mounted on the substrate 131, the reflection portion 135 having a liquid phase is applied to the periphery of the light emitting diode chip 133 to surround the light emitting diode chip 133. Here, the pair of leads 132 serves to block the liquid reflection portion 135 having a liquid state from overflowing.

In addition, the reflection portion 135 has a white color to facilitate reflection of light emitted from the light emitting diode chip 133. The light reflected by the reflection portion 135 exits through the wavelength conversion portion 136 disposed on the reflection portion. Thus, light emitted from a side surface of the light emitting diode chip 133, which is not a light exiting surface, is reflected by the reflection portion 135 and guided to the wavelength conversion portion 136.

The wavelength conversion portion 136 is formed on the light emitting diode chip 133 and the reflection portion 135. That is, the wavelength conversion portion 136 adjoins an upper surface of the light emitting diode chip 133 including the light exiting surface, and is wider than the light emitting diode chip 133 to cover an upper surface of the reflection portion 135. As used herein, the term “light exiting surface” refers to a surface of the light emitting diode chip 133 through which light from the light emitting diode chip exits. In addition, the wavelength conversion portion 136 may include a phosphor. The phosphor serves to convert the wavelength of the light emitted from the light emitting diode chip 133.

With this structure, the side-view light-emitting diode package 130 can be reduced in thickness to 0.3T and allows heat generated in the light emitting diode chip 133 to quickly dissipate through the substrate 131.

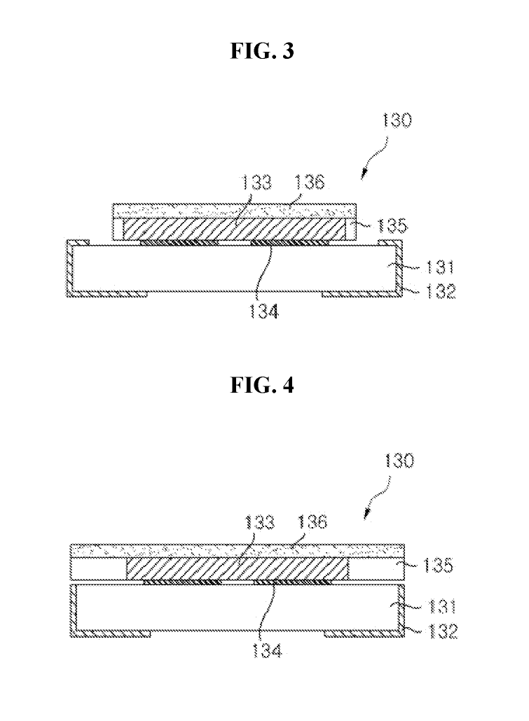

FIG. 3 is a view of a side-view light-emitting diode package for a backlight unit according to another exemplary embodiment.

Referring to FIG. 3, a side-view light-emitting diode package 130 according to this embodiment includes a substrate 131, a pair of leads 132, a light emitting diode chip 133, a reflection portion 135, and a wavelength conversion portion 136. Description of the same components as those of the above embodiment will be omitted.

For the side-view light-emitting diode package 130 according to this embodiment, the substrate 131 formed with the pair of leads 132 and the light emitting diode chip 133 formed with the reflection portion 135 and the wavelength conversion portion are separately fabricated. For example, after the pair of leads 132 is formed on the substrate 131, the reflection portion 135 and the wavelength conversion portion 136 are formed on the light emitting diode chip 133. Then, the light emitting diode chip 133 is mounted on the substrate 131, thereby fabricating a side-view light-emitting diode package 130, as shown in FIG. 3.

Here, the reflection portion 135 is formed to a predetermined thickness on a side surface of the light emitting diode chip 133 to surround the side surface thereof, and the wavelength conversion portion 136 is formed on a light exiting surface of the light emitting diode chip 133 formed with the reflection portion 135 to cover the reflection portion 135. Here, the thickness of the reflection portion 135 is determined to prevent light emitted from the light emitting diode chip 133 from passing through the reflection portion 135.

The side-view light-emitting diode package 130 according to this embodiment is easy to fabricate, since the substrate 131 and the light emitting diode chip 133 are separately manufactured and then coupled to each other.

FIG. 4 is a cross section view of a side-view light-emitting diode package for a backlight unit according to another exemplary embodiment.

Referring to FIG. 4, the side-view light-emitting diode package 130 according to this exemplary embodiment includes a substrate 131, a pair of leads 132, a light emitting diode chip 133, a reflection portion 135, and a wavelength conversion portion 136. Description of the same components as those of the above embodiment will be omitted.

For the side-view light-emitting diode package 130 according to this embodiment, the substrate 131 formed with the pair of leads 132 and the light emitting diode chip 133 formed with the reflection portion 135 and the wavelength conversion portion are separately fabricated. For example, after the pair of leads 132 is formed on the substrate 131, the light emitting diode chip 133 is mounted on the substrate 131, thereby fabricating a side-view light-emitting diode package 130 as shown in FIG. 4.

Here, the pair of leads 132 is not formed on an upper surface of the substrate 131, as shown in FIG. 4. That is, the pair of leads 132 is bent to extend from a side surface of the substrate 131 to a lower surface of the substrate 131.

In addition, the reflection portion 135 having a predetermined thickness is formed around the light emitting diode chip 133 to surround a side surface of the light emitting diode chip 133. Here, the thickness of the reflection portion 135 is equal to the width of the substrate 131. That is, when the light emitting diode chip 133 is mounted on the substrate 131, opposite ends of the reflection portion 135 are flush with opposite ends of the substrate 131, respectively, as shown in FIG. 4.

The wavelength conversion portion 136 is formed to cover both a light exiting surface of the light emitting diode chip 133 and the reflection portion 135. Accordingly, the wavelength conversion portion 136 is larger than the light emitting diode chip 133, whereby light from the emitting diode chip 133 can more efficiently exit the side-view light-emitting diode package.

Although some exemplary embodiments have been described herein, it should be understood that these embodiments are provided for illustration only and are not to be construed in any way as limiting the present inventive concepts. The scope of the present inventive concepts should be defined by the appended claims and equivalents thereof.

1. A backlight unit, comprising:
a light guide plate; and
a light emitting diode package coupled to a side surface of the light guide plate and configured to emit light into the light guide plate,
wherein the light emitting diode package comprises:
a substrate;
a pair of leads disposed at opposite ends of the substrate;
a light emitting diode chip mounted on the substrate;
a reflection portion surrounding a side surface of the light emitting diode chip; and
a wavelength conversion portion formed disposed on the light emitting diode chip and the reflection portion.

2. The backlight unit according to claim 1, wherein the reflection portion covers the substrate having the light emitting diode chip mounted thereon.

3. The backlight unit according to claim 1, wherein the reflection portion is spaced apart from the substrate.

4. The backlight unit according to claim 1, wherein the reflection portion has a width configured such that opposite ends of the reflection portion are flush with opposite ends of the pair of leads, respectively, and the wavelength conversion portion completely covers an upper surface of the reflection portion.

5. The backlight unit according to claim 4, wherein the pair of leads is bent to extend from the opposite ends of the substrate to a lower surface of the substrate.

6. The backlight unit according to claim 1, wherein the pair of leads extends from an upper surface of the substrate to a lower surface of the substrate to surround the opposite ends of the substrate.

7. A side-view light-emitting diode package, comprising:
a substrate;
a pair of leads formed at opposite ends of the substrate;
a light emitting diode chip mounted on the substrate;
a reflection portion surrounding a side surface of the light emitting diode chip; and
a wavelength conversion portion disposed on the light emitting diode chip and the reflection portion.

8. The side-view light-emitting diode package according to claim 7, wherein the reflection portion covers the substrate, and the light emitting diode chip is mounted the substrate.

9. The side-view light-emitting diode package according to claim 7, wherein the reflection portion is spaced apart from the substrate.

10. The side-view light-emitting diode package according to claim 9, wherein the reflection portion has a width configured such that opposite ends of the reflection portion are flush with opposite ends of the pair of leads, respectively, and the wavelength conversion portion completely covers an upper surface of the reflection portion.

11. The side-view light-emitting diode package according to claim 10, wherein the pair of leads is bent to extend from the opposite ends of the substrate to a lower surface of the substrate.

12. The side-view light-emitting diode package according to claim 7, wherein the pair of leads extends from an upper surface of the substrate to a lower surface of the substrate to surround the opposite ends of the substrate.
